(19) United States
(12) Patent Application Publication
(10) Pub. No.: US 2026/0090035 A1
(43) Pub. Date: Mar. 26, 2026

(54) SWITCHING ELEMENT

(71) Applicants: DENSO CORPORATION, Kariya-city (JP); TOYOTA JIDOSHA KABUSHIKI KAISHA, Toyota-shi, Aichi-ken (JP); MIRISE Technologies Corporation, Nisshin-shi (JP); NATIONAL INSTITUTE OF ADVANCED INDUSTRIAL SCIENCE AND TECHNOLOGY, Tokyo (JP); FUJI ELECTRIC CO., LTD., Kawasaki-shi (JP)

(72) Inventors: Eiji KAGOSHIMA, Nisshin-shi (JP); Misa TAKAHASHI, Chofu-shi (JP); Manami IWATA, Chofu-shi (JP); Shinsuke HARADA, Tsukuba-shi (JP); Syunki NARITA, Matsumoto-shi (JP)

(21) Appl. No.: 19/321,955

(22) Filed: Sep. 8, 2025

(30) Foreign Application Priority Data
Sep. 26, 2024 (JP) 2024-167847

(51) Int. Cl. H10D 62/10; H10D 30/66; H10D 62/60

(52) U.S. Cl. CPC H10D 62/107; H10D 30/668; H10D 62/60

(57) ABSTRACT

In a switching element, a semiconductor substrate includes at least one of a first lower p-layer in contact with a gate insulating film from below and a drift layer from above or a second lower p-layer in contact with a body layer from below and the drift layer from above. The at least one of the first lower p-layer or the second lower p-layer includes a high-concentration layer having a p-type impurity concentration equal to or greater than half of a maximum p-type impurity concentration, and a low-concentration layer having a p-type impurity concentration smaller than the half of the maximum p-type impurity concentration. The low-concentration layer has a lower low-concentration layer between the high-concentration layer and the drift layer. A part of the lower low-concentration layer having a p-type impurity concentration higher than an average p-type impurity concentration of the lower low-concentration layer has a predetermined thickness.

### CROSS REFERENCE TO RELATED APPLICATION

The present application claims the benefit of priority from Japanese Patent Application No. 2024-167847 filed on Sep. 26, 2024. The entire disclosures of the above application are incorporated herein by reference.

### TECHNICAL FIELD

The present disclosure relates to a switching element.

### BACKGROUND

It has been known that, when cosmic rays enter a switching element, electron-hole pairs are generated inside a semiconductor substrate, decreasing the breakdown voltage of the switching element. In order to suppress the decrease in breakdown voltage due to the cosmic rays, it is conceivable to adjust distribution of an n-type impurity concentration in a drift layer.

### SUMMARY

A switching element according to an aspect of the present disclosure, includes a semiconductor substrate made of silicon carbide and a gate electrode facing the semiconductor substrate via a gate insulating film. The semiconductor substrate may include: an n-type source layer in contact with the gate insulating film; a p-type body layer in contact with the gate insulating film and the source layer; an n-type drift layer in contact with the gate insulating film and the body layer and separated from the source layer by the body layer; and at least one of a first lower p-layer in contact with the gate insulating film from below and in contact with the drift layer from above or a second lower p-layer in contact with the body layer from below and in contact with the drift layer from above. The at least one of the first lower p-layer or the second lower p-layer may include: a high-concentration layer having a p-type impurity concentration equal to or greater than half of a maximum value of a p-type impurity concentration in the at least one of the first lower p-layer or the second lower p-layer; and a low-concentration layer having a p-type impurity concentration smaller than the half of the maximum value. The low-concentration layer may have a lower low-concentration layer disposed between the high-concentration layer and the drift layer in a thickness direction of the semiconductor substrate. A part of the lower low-concentration layer having a p-type impurity concentration higher than an average value A of the p-type impurity concentration of the lower low-concentration layer may have a predetermined thickness that is greater than a smaller of thicknesses x1 and x2 obtained by following mathematical equations (1) and (2):

$$\begin{matrix}x 1 = \frac{C \cdot T}{A} & ( 1 ) \\ \{ \begin{matrix}x 2 = \sqrt{\frac{2 \cdot ε}{q \cdot A} \cdot \frac{C}{A + C} \cdot ( {V}_{bi} + {V}_{BV} )} \\ {V}_{bi} = \frac{298 k}{q} ln ( \frac{A \cdot C}{{n}_{i}^{2}} )\end{matrix} & ( 2 )\end{matrix}$$

in which a symbol C represents an average value of an n-type impurity concentration of the drift layer below the at least one of the first lower p-layer or the second lower p-layer, a symbol T represents a thickness of the drift layer below the at least one of the first lower p-layer or the second lower p-layer, a symbol ε represents a dielectric constant of the silicon carbide, a symbol q is an elementary charge, a symbol V_{bi} represents a built-in potential at an interface between the low-concentration layer and the drift layer, a symbol V_{BV} represents a maximum rated voltage between a drain and a source of the switching element, a symbol k represents a Boltzmann constant, and a symbol nᵢ is an intrinsic carrier density of the silicon carbide.

### BRIEF DESCRIPTION OF DRAWINGS

Objects, features and advantages of the present disclosure will become more apparent from the following detailed description made with reference to the accompanying drawings, in which like parts are designated by like reference numbers and in which:

FIG. 1 is a cross-sectional view of a switching element according to a first embodiment;

FIG. 2 is a graph showing an impurity concentration distribution in a lower p-layer according to the first embodiment;

FIG. 3 is a cross-sectional view of a switching element according to a first modified example of the first embodiment;

FIG. 4 is a graph showing an impurity concentration distribution in a lower p-layer according to the first modified example of the first embodiment;

FIG. 5 is a cross-sectional view of a switching element according to a second modified example of the first embodiment;

FIG. 6 is a cross-sectional view of a switching element according to a third modified example of the first embodiment;

FIG. 7 is a cross-sectional view of a switching element according to a second embodiment;

FIG. 8 is a cross-sectional view of a switching element according to a first modified example of the second embodiment; and

FIG. 9 is a cross-sectional view of a switching element according to a second modified example of the second embodiment.

### DETAILED DESCRIPTION

In a switching element having a semiconductor substrate made of silicon carbide, a technique has been known in which a p-layer (hereinafter referred to as a lower p-layer) is provided in a drift layer. The lower p-layer can reduce the electric field applied to a gate insulating film. In the case where the lower p-layer is provided, a depletion layer extends from the boundary between the drift layer and the lower p-layer into the lower p-layer when the switching element is in an off state. Since a large number of crystal defects exist in the lower p-layer, if the depletion layer extends widely in the lower p-layer, a leakage current of the switching element is likely to increase. The present disclosure provides a technique for suppressing the leakage current in a switching element having a lower p-layer.

According to an aspect of the present disclosure, a switching element includes a semiconductor substrate made of silicon carbide and a gate electrode facing the semiconductor substrate via a gate insulating film. The semiconductor substrate includes: an n-type source layer in contact with the gate insulating film; a p-type body layer in contact with the gate insulating film and the source layer; an n-type drift layer in contact with the gate insulating film and the body layer and separated from the source layer by the body layer; and at least one of a first lower p-layer in contact with the gate insulating film from below and in contact with the drift layer from above or a second lower p-layer in contact with the body layer from below and in contact with the drift layer from above. The at least one of the first lower p-layer or the second lower p-layer includes: a high-concentration layer having a p-type impurity concentration equal to or greater than half of a maximum value of a p-type impurity concentration in the at least one of the first lower p-layer or the second lower p-layer; and a low-concentration layer having a p-type impurity concentration smaller than the half of the maximum value. The low-concentration layer has a lower low-concentration layer disposed between the high-concentration layer and the drift layer in a thickness direction of the semiconductor substrate. A part of the lower low-concentration layer having a p-type impurity concentration higher than an average value A of the p-type impurity concentration of the lower low-concentration layer has a predetermined thickness that is greater than a smaller of thicknesses x1 and x2 obtained by following mathematical equations (1) and (2):

$$\begin{matrix}x 1 = \frac{C \cdot T}{A} & ( 1 ) \\ \{ \begin{matrix}x 2 = \sqrt{\frac{2 \cdot ε}{q \cdot A} \cdot \frac{C}{A + C} \cdot ( {V}_{bi} + {V}_{BV} )} \\ {V}_{bi} = \frac{298 k}{q} ln ( \frac{A \cdot C}{{n}_{i}^{2}} )\end{matrix} & ( 2 )\end{matrix}$$

in which a symbol C represents an average value of an n-type impurity concentration of the drift layer below the at least one of the first lower p-layer or the second lower p-layer, a symbol T represents a thickness of the drift layer below the at least one of the first lower p-layer or the second lower p-layer, a symbol ε represents a dielectric constant of the silicon carbide, a symbol q is an elementary charge, a symbol V_{bi} represents a built-in potential at an interface between the low-concentration layer and the drift layer, a symbol V_{BV} represents a maximum rated voltage between a drain and a source of the switching element, a symbol k represents a Boltzmann constant, and a symbol nᵢ is an intrinsic carrier density of the silicon carbide.

In the above mathematical equation (2), the maximum rated voltage V_{BV} is a value that is expressed as a positive value when the drain has a higher potential than the source.

The above thickness x1 corresponds to a width of a depletion layer that extends into the low-concentration layer when the drift layer below the lower p-layer is depleted throughout its thickness. The thickness x2 corresponds to a width of the depletion layer that extends into the low-concentration layer when the maximum rated voltage V_{BV} is applied to the switching element. In a case where the switching element is of a punch-through type, the drift layer is depleted when the drain-source voltage is lower than the maximum rated voltage V_{BV}, and therefore the thickness x1 is smaller than the thickness x2. In a case where the switching element is of a non-punch-through type, the thickness x2 is smaller than the thickness x1. Therefore, the smaller value of the thicknesses x1 and x2 indicates the maximum width of the depletion layer that extends into the low-concentration layer in an operating environment of the switching element. In this switching element, the predetermined thickness of the part of the lower low-concentration layer having the p-type impurity concentration higher than the average p-type impurity concentration A of the low-concentration layer is greater than the maximum width of the depletion layer extending into the low-concentration layer. As such, the depletion layer does not reach the high-concentration layer. Since the depletion layer does not reach the high-concentration layer where crystal defects exist at a high density, the leakage current is less likely to occur in the switching element.

In an embodiment of the present disclosure, a trench may be formed in an upper surface of the semiconductor substrate. The gate insulating film and the gate electrode may be disposed in the trench. The semiconductor substrate may have the first lower p-layer that is in contact with the gate insulating film at a bottom surface of the trench.

In an embodiment of the present disclosure, the switching element may have the second lower p-layer that is in contact with the body layer from below.

### First Embodiment

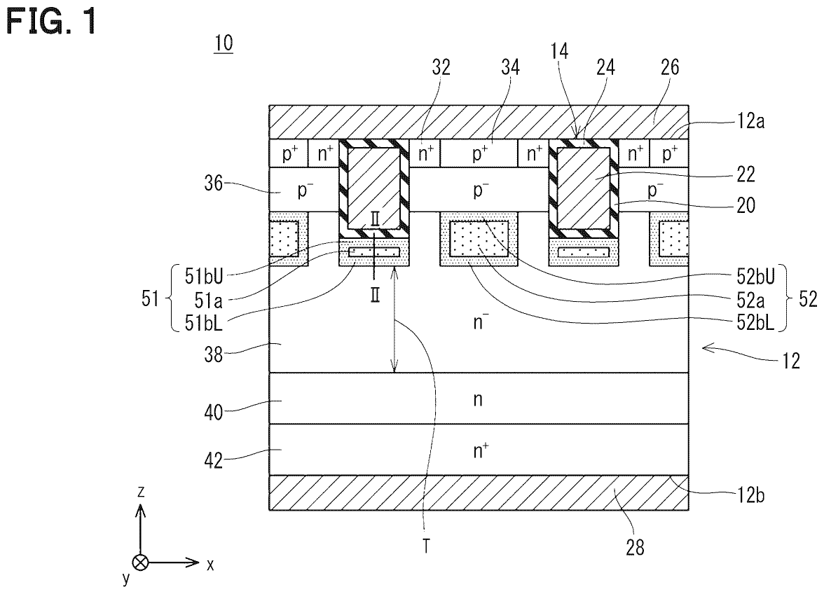

In a first embodiment, a switching element 10 shown in FIG. 1 is a trench-gate metal oxide semiconductor field effect transistor (MOSFET). The switching element 10 is designed for use in the stratosphere or at higher altitudes (for example, outer space), and has a structure capable of suppressing the effects of cosmic rays. The switching element 10 includes a semiconductor substrate 12, a gate electrode 22, a gate insulating film 20, a source electrode 26, and a drain electrode 28.

The semiconductor substrate 12 is made of silicon carbide (SiC). Hereinafter, a direction parallel to an upper surface 12a of the semiconductor substrate 12 is referred to as an x direction, and a direction parallel to the upper surface 12a and perpendicular to the x direction is referred to as a y direction. Further, a direction along the thickness of the semiconductor substrate 12, i.e., the thickness direction of the semiconductor substrate 12 is referred to as a z direction. The semiconductor substrate 12 is formed with multiple trenches 14 in the upper surface 12a. Each of the trenches 14 extends linearly along the y direction in the upper surface 12a. The trenches 14 are spaced apart from each other in the x direction.

The gate insulating film 20 covers an inner surface of each of the trenches 14. The gate electrode 22 is disposed inside of each of the trenches 14. The gate electrode 22 is insulated from the semiconductor substrate 12 by the gate insulating film 20. An upper surface of the gate electrode 22 is covered with an interlayer insulating film 24.

The source electrode 26 covers the upper surface 12a of the semiconductor substrate 12. The source electrode 26 is insulated from the gate electrode 22 by the interlayer insulating film 24. The drain electrode 28 covers a lower surface 12b of the semiconductor substrate 12.

The semiconductor substrate 12 has multiple source layers 32, multiple contact layers 34, a body layer 36, a drift layer 38, a buffer layer 40, a drain layer 42, multiple first lower p-layers 51, and multiple second lower p-layers 52.

Each of the source layers 32 is an n-type layer having a high n-type impurity concentration. Each of the source layers 32 is in ohmic contact with the source electrode 26 at the upper surface 12a. Each of the source layers 32 is in contact with the gate insulating film 20 at the upper end of a side surface of the corresponding trench 14.

Each of the contact layers 34 is a p-type layer having a high p-type impurity concentration. Each of the contact layers 34 is in ohmic contact with the source electrode 26 at the upper surface 12a.

The body layer 36 is a p-type layer having a p-type impurity concentration lower than that of the contact layer 34. The body layer 36 is disposed below the source layer 32 and the contact layer 34. The body layer 36 is in contact with the source layer 32 and the contact layer 34 from below. The body layer 36 is in contact with the gate insulating film 20 at the side surface of the trench 14 below the source layer 32.

The drift layer 38 is an n-type layer having an n-type impurity concentration lower than that of the source layer 32. The n-type impurity concentration of the drift layer 38 is 9×10¹⁷ cm⁻³ or less. The drift layer 38 is disposed below the body layer 36. The drift layer 38 is in contact with the body layer 36 from below. The drift layer 38 is separated from the source layer 32 by the body layer 36. The drift layer 38 is in contact with the gate insulating film 20 at the side surface of the trench 14 below the body layer 36. The drift layer 38 is distributed from a position in contact with the body layer 36 to a position below the lower end of each trench 14.

The buffer layer 40 is an n-type layer having an n-type impurity concentration higher than that of the drift layer 38. The n-type impurity concentration of the buffer layer 40 is higher than 9×10¹⁷ cm⁻³. The buffer layer 40 is in contact with the drift layer 38 from below.

The drain layer 42 is an n-type layer having an n-type impurity concentration higher than that of the buffer layer 40. The drain layer 42 is in contact with the buffer layer 40 from below. The drain layer 42 is in ohmic contact with the drain electrode 28 at the lower surface 12b of the semiconductor substrate 12.

Each of the first lower p-layers 51 is disposed below the corresponding trench 14. Each of the first lower p-layers 51 is in contact with the gate insulating film 20 at the bottom surface of the corresponding trench 14. That is, each of the first lower p-layers 51 is in contact with the gate insulating film 20 from below. Each of the first lower p-layers 51 is in contact with the drift layer 38 from above. The bottom surface and side surfaces of each of the first lower p-layers 51 are in contact with the drift layer 38. Each of the first lower p-layers 51 is connected to the body layer 36 via a p-type layer (not shown). Therefore, the potential of each of the first lower p-layers 51 is substantially equal to the potential of the body layer 36.

Each of the second lower p-layers 52 is disposed below the body layer 36. Each of the second lower p-layers 52 extends longitudinally along the y direction in parallel to the trenches 14. Each of the second lower p-layers 52 is in contact with the body layer 36 from below. Each of the second lower p-layers 52 is in contact with the drift layer 38 from above. The bottom surface and side surfaces of each of the second lower p-layers 52 are in contact with the drift layer 38.

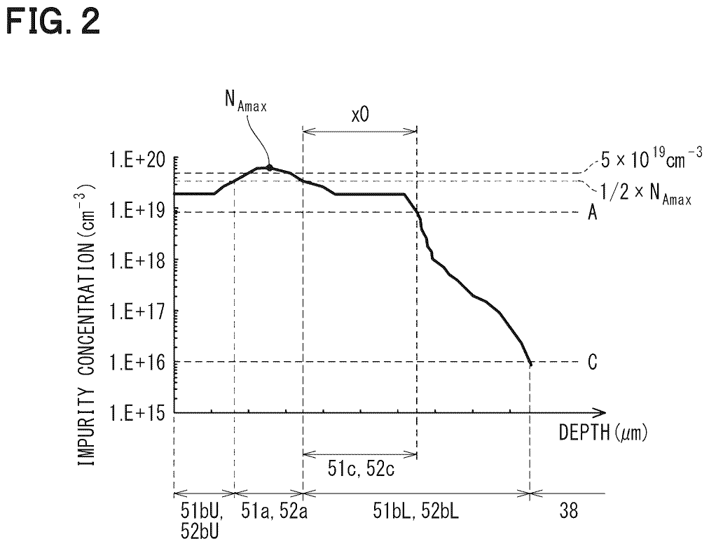

FIG. 2 shows the distribution of p-type impurity concentration at a position taken along a line II-II in FIG. 1, that is, the distribution of p-type impurity concentration along the z direction of the lower p-layer 51. In FIG. 2, a symbol N_{Amax} represents a maximum value of the p-type impurity concentration in the first lower p-layer 51, and a symbol C represents an average value of the n-type impurity concentration of a part of the drift layer 38 below the first lower p-layer 51. The region having the p-type impurity concentration higher than the value C serves as the first lower p-layer 51. The first lower p-layer 51 includes a high-concentration layer 51a having a p-type impurity concentration that is equal to or more than half of the maximum value N_{Amax}, and a low-concentration layer 51b having a p-type impurity concentration that is less than half of the maximum value N_{Amax}. The low-concentration layer 51b is a p-type layer including an upper low-concentration layer 51bU and a lower low-concentration layer 51bL. In the present embodiment, the maximum value N_{Amax} is 5×10¹⁹ cm⁻³ or more. As shown in FIG. 1, the high-concentration layer 51a is disposed substantially in the center of the first lower p-layer 51, and the low-concentration layer 51b is disposed around the high-concentration layer 51a. Thus, the low-concentration layer 51b includes the upper low-concentration layer 51bU and the lower low-concentration layer 51bL. The upper low-concentration layer 51bU is disposed above the high-concentration layer 51a, and the lower low-concentration layer 51bL is disposed below the high-concentration layer 51a. The lower low-concentration layer 51bL is disposed between the high-concentration layer 51a and the drift layer 38 in the z direction. Moreover, the average value A shown in FIG. 2 is the average value of the p-type impurity concentration of the low-concentration layer 51b. The lower low-concentration layer 51bL has a region 51c having a p-type impurity concentration higher than the average value A. The region 51c is in contact with the high-concentration layer 51a from below.

The thickness x0 of the region 51c is greater than the smaller of thicknesses x1 and x2 that are obtained by the following mathematical equations (1) and (2).

$$\begin{matrix}x 1 = \frac{C \cdot T}{A} & ( 1 ) \\ \{ \begin{matrix}x 2 = \sqrt{\frac{2 \cdot ε}{q \cdot A} \cdot \frac{C}{A + C} \cdot ( {V}_{bi} + {V}_{BV} )} \\ {V}_{bi} = \frac{298 k}{q} ln ( \frac{A \cdot C}{{n}_{i}^{2}} )\end{matrix} & ( 2 )\end{matrix}$$

In the equations (1) and (2), a symbol T represents a thickness of the drift layer 38 below the first lower p-layer 51, as shown in FIG. 1. A symbol ε represents a dielectric constant of silicon carbide. A symbol q represents an elementary charge. A symbol V_{bi} represents a built-in potential at the interface between the low-concentration layer 51b and the drift layer 38. A symbol V_{BV} represents a maximum rated voltage that can be applied between the drain and the source of the switching element 10. A symbol k represents the Boltzmann constant. A symbol nᵢ represents an intrinsic carrier density of silicon carbide.

In the second lower p-layer 52, the p-type impurity concentration is distributed substantially similarly to the p-type impurity concentration in the first lower p-layer 51 (i.e., FIG. 2). The second lower p-layer 52 includes a high-concentration layer 52a and a low-concentration layer 52b. The low-concentration layer 52b is a p-type layer including an upper low-concentration layer 52bU and a lower low-concentration layer 52bL. The high-concentration layer 52a has a p-type impurity concentration that is half or more of the maximum value N_{Amax} of the p-type impurity concentration of the second lower p-layer 52, and the low-concentration layer 52b has a p-type impurity concentration that is less than half of the maximum value N_{Amax}. As shown in FIG. 1, the high-concentration layer 52a is disposed substantially in the center of the second lower p-layer 52, and the low-concentration layer 52b is disposed around the high-concentration layer 52a. The low-concentration layer 52b includes the upper low-concentration layer 52bU and the lower low-concentration layer 52bL. The upper low-concentration layer 52bU is disposed above the high-concentration layer 52a, and the lower low-concentration layer 52bL is disposed below the high-concentration layer 52a. The lower low-concentration layer 52bL has a region 52c that has a p-type impurity concentration higher than an average value A of the p-type impurity concentration in the low-concentration layer 52b. The region 52c is in contact with the high-concentration layer 52a from below. When the above mathematical equations (1) and (2) are applied to the drift layer 38 below the second lower p-layer 52, the thickness x0 of the region 52c of the second lower p-layer 52 is greater than the smaller of the thicknesses x1 and x2.

The following describes an operation of the switching element 10. When the switching element 10 is in use, a higher potential is applied to the drain electrode 28 than to the source electrode 26. When a potential equal to or higher than a gate threshold is applied to the gate electrode 22, a channel is formed in the body layer 36 in an area adjacent to the gate insulating film 20. Thus, the source layer 32 and the drift layer 38 are connected by the channel. As a result, electrons flow from the source layer 32 to the drain layer 42 through the channel, the drift layer 38, and the buffer layer 40. That is, the switching element 10 is turned on. When the potential of the gate electrode 22 is reduced to a potential lower than the gate threshold, the channel disappears and the switching element 10 is turned off.

When the switching element 10 is turned off, a reverse voltage is applied to the interface (i.e., the pn junction) between a p-type layer composed of the body layer 36, the first lower p-layer 51 and the second lower p-layer 52, and the drift layer 38. As a result, a depletion layer extends from the pn junction into both the p-type layer and the drift layer 38.

In a case where the switching element 10 is of a punch-through type, the entire drift layer 38 is depleted when the drain-source voltage of the switching element 10 is lower than the maximum rated voltage. Therefore, in the punch-through type, the maximum width of the depletion layer extending in the drift layer 38 is equal to the thickness T of the drift layer 38. In this case, the width of the depletion layer extending from the lower surface of the first lower p-layer 51 (i.e., the pn junction) into the first lower p-layer 51 corresponds to the thickness x1 obtained by the above mathematical equation (1). The width of the depletion layer extending from the lower surface of the second lower p-layer 52 (i.e., the pn junction) into the second lower p-layer 52 also corresponds to the thickness x1 obtained by the above mathematical equation (1).

In a case where the switching element 10 is of a non-punch-through type, when the maximum rated voltage is applied between the drain and the source of the switching element 10, the depletion layer having a width according to the maximum rated voltage is formed in the drift layer 38. In this case, the width of the depletion layer extending from the lower surface of the first lower p-layer 51 (i.e., the pn junction) into the first lower p-layer 51 corresponds to the thickness x2 obtained by the above mathematical equation 2. The width of the depletion layer extending from the lower surface of the second lower p-layer 52 (i.e., the pn junction) into the second lower p-layer 52 also corresponds to the thickness x2 obtained by the above mathematical equation 2.

Thus, the smaller of the thicknesses x1 and x2 represents the maximum width of the depletion layer extending into the first lower p-layer 51 and the second lower p-layer 52. In the first embodiment, the thickness x0 of the region 51c, which is a part of the lower low-concentration layer 51bL disposed below the high-concentration layer 51a, is larger than the smaller of the thicknesses x1 and x2. Furthermore, the thickness x0 of the region 52c, which is a part of the lower low-concentration layer 52bL disposed below the high-concentration layer 52a, is larger than the smaller of the thicknesses x1 and x2. Therefore, when the switching element 10 is turned off, the depletion layer does not reach the high-concentration layers 51a and 52a. Since the p-type impurity concentrations of the high-concentration layers 51a and 52a are high, crystal defects exist in the high-concentration layers 51a and 52a at a high density. When the depletion layer reaches the high-concentration layers 51a and 52a having a high density of crystal defects, a high leakage current occurs. In contrast, in the present embodiment, since the depletion layer does not reach the high-concentration layers 51a and 52a, the leakage current is less likely to occur.

When cosmic rays enter the lower p-layer 51 while the switching element 10 is in an off state, electron-hole pairs are generated in the lower p-layer 51. When the holes generated in the lower p-layer 51 are accelerated by the electric field and injected into the gate insulating film 20, the insulating property of the gate insulating film 20 is likely to deteriorate. In contrast to this, in the first embodiment, the maximum value N_{Amax} of the p-type impurity concentration of the lower p-layer 51 is 5×10¹⁹ cm⁻³ or more, and the space charge of the lower p-layer 51 is significantly negative. Therefore, even if holes are generated in the lower p-layer 51 due to the entering of cosmic rays, an electric field directing toward the gate insulating film 20 is less likely to occur in the lower p-layer 51, and the injection of holes into the gate insulating film 20 is suppressed. As a result, deterioration of the gate insulating film 20 is suppressed. Even when the cosmic rays enter the lower p-layer 52, the injection of holes into the gate insulating film 20 is similarly suppressed. Therefore, the deterioration of the gate insulating film 20 is suppressed.

As described above, in the switching element 10 of the first embodiment, the first lower p-layer 51 and the second lower p-layer 52 can suppress the injection of holes caused by the cosmic rays into the gate insulating film 20, and can suppress deterioration of the gate insulating film 20. Furthermore, the leakage current caused by the first lower p-layer 51 and the second lower p-layer 52 can be suppressed.

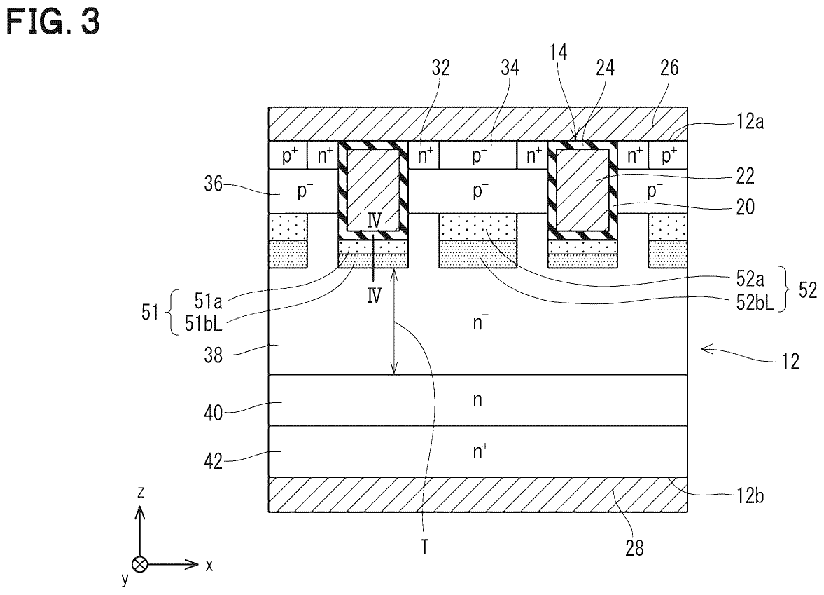

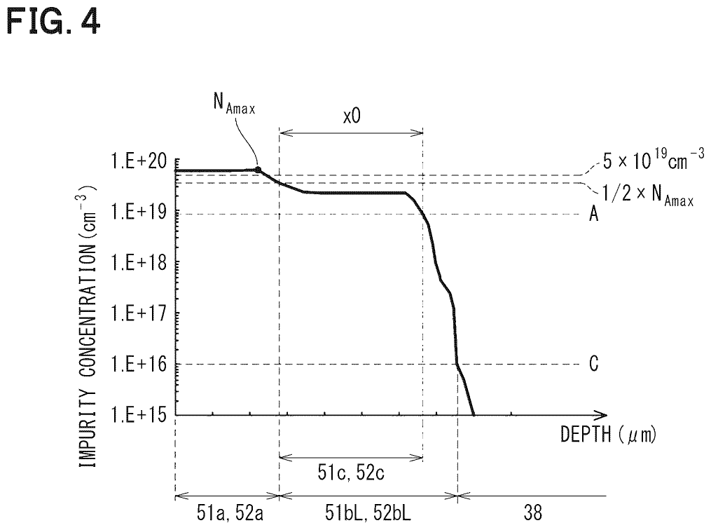

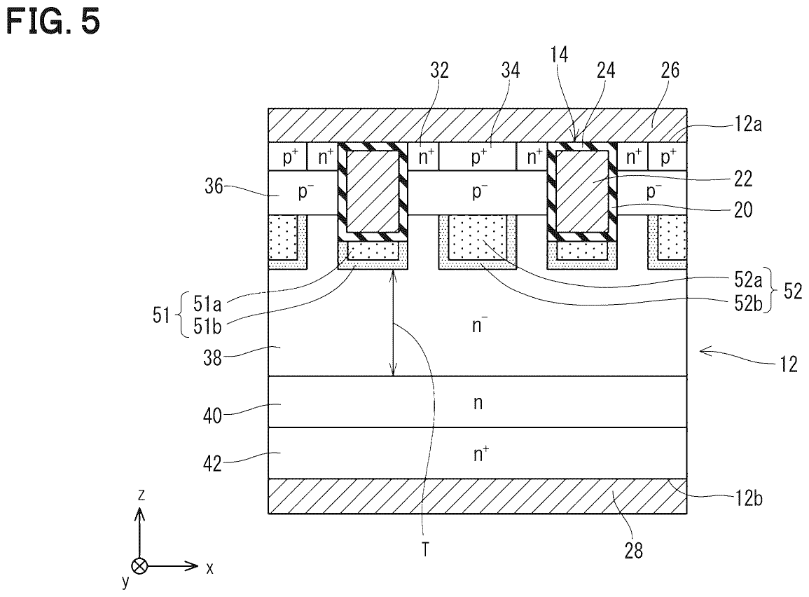

In the first embodiment, the upper low-concentration layer 51bU is provided above the high-concentration layer 51a. Alternatively, as a modified example, the upper low-concentration layer 51bU may not be provided, and the high-concentration layer 51a may be in direct contact with the gate insulating film 20, as shown in FIGS. 3 and 4. In addition, in the first embodiment, the upper low-concentration layer 52bU is provided above the high-concentration layer 52a. Alternatively, as shown in FIGS. 3 and 4, the upper low-concentration layer 52bU may not be provided, and the high-concentration layer 52a may be in direct contact with the body layer 36. In these configurations, since the lower low-concentration layers 51bL and 52bL are present below the high-concentration layers 51a and 52a, the depletion layer does not reach the high-concentration layers 51a and 52a, as in the first embodiment. Therefore, the leakage current can be suppressed. In FIG. 4, the maximum value N_{Amax} may be 5×10¹⁹ cm⁻³ or more. In a case where the upper low-concentration layers 51bU and 52bU are not provided, the low-concentration layers 51b and 52b may be provided on the sides and the bottom of the high-concentration layers 51a and 52a, as shown in FIG. 5, as another modified example.

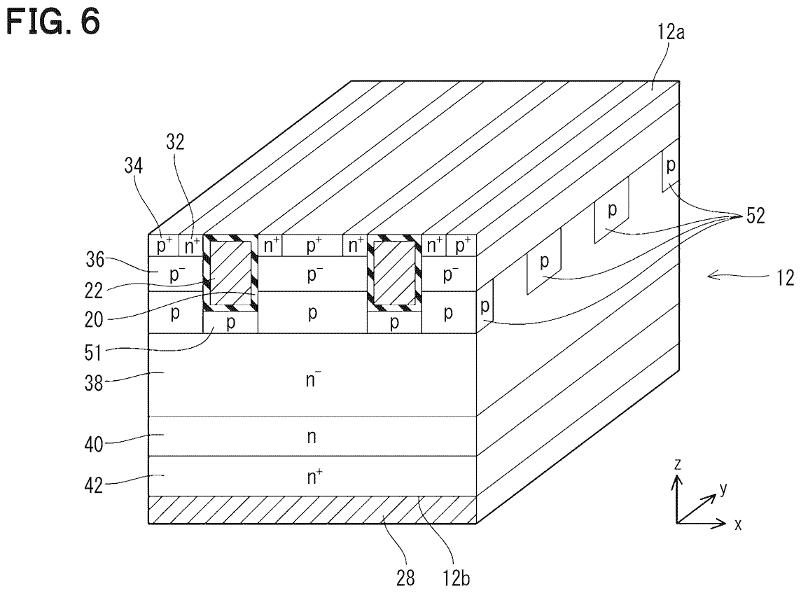

In the first embodiment, the second lower p-layer 52 extends along the y direction. Alternatively, as a modified example, the second lower p-layer 52 may extend along the x direction (i.e., the direction intersecting with the trenches 14), as shown in FIG. 6. In this configuration, the first lower p-layer 51 and the second lower p-layer 52 are connected to each other at their intersections.

In the first embodiment, the buffer layer 40 is provided between the drift layer 38 and the drain layer 42. Alternatively, the buffer layer 40 may not be present and the drift layer 38 may be in contact with the drain layer 42.

In the first embodiment, both the first lower p-layer 51 and the second lower p-layer 52 are provided in the semiconductor substrate 12. Alternatively, only one of the first lower p-layer 51 and the second lower p-layer 52 may be provided.

### Second Embodiment

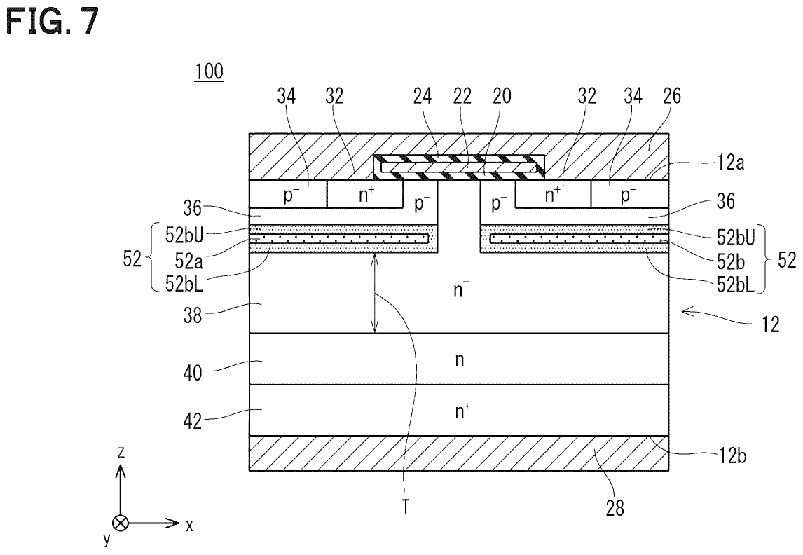

A switching element 100 according to a second embodiment shown in FIG. 7 is a planar type MOSFET. The switching element 100 is designed for use in the stratosphere or at higher altitudes (e.g., outer space), and has a structure capable of suppressing the effects of cosmic rays. In the following description, the same reference numerals as those in the first embodiment are used to indicate the respective parts of the switching element 100 in the second embodiment. The switching element 100 includes a semiconductor substrate 12, a gate electrode 22, a gate insulating film 20, a source electrode 26, and a drain electrode 28.

The semiconductor substrate 12 is made of silicon carbide (SiC). The gate insulating film 20 covers a part of the upper surface 12a of the semiconductor substrate 12. The gate electrode 22 is disposed above the gate insulating film 20. The gate electrode 22 is insulated from the semiconductor substrate 12 by the gate insulating film 20. The upper surface and side surfaces of the gate electrode 22 are covered with an interlayer insulating film 24. The source electrode 26 covers the upper surface 12a of the semiconductor substrate 12. The source electrode 26 is insulated from the gate electrode 22 by the interlayer insulating film 24. The drain electrode 28 covers a lower surface 12b of the semiconductor substrate 12.

The semiconductor substrate 12 has multiple source layers 32, multiple contact layers 34, multiple body layers 36, a drift layer 38, a buffer layer 40, a drain layer 42 and multiple lower p-layers 52.

Each of the source layers 32 is an n-type layer having a high n-type impurity concentration. Each of the source layers 32 is in ohmic contact with the source electrode 26 at the upper surface 12a. Each of the source layers 32 is in contact with the gate insulating film 20 at the upper surface 12a.

Each of the contact layers 34 is a p-type layer having a high p-type impurity concentration. Each of the contact layers 34 is in ohmic contact with the source electrode 26 at the upper surface 12a.

Each of the body layers 36 is a p-type layer having a p-type impurity concentration lower than the contact layer 34. The body layers 36 are arranged at intervals in the x direction. Each of the body layers 36 is disposed around the source layer 32 and the contact layer 34. Each of the body layers 36 is in contact with the source layer 32 and the contact layer 34 from below. Each of the body layers 36 is distributed onto the side of the source layer 32 and is in contact with the side surface of the source layer 32. Each of the body layers 36 is in contact with the gate insulating film 20 at a position adjacent to the source layer 32.

The drift layer 38 is an n-type layer having an n-type impurity concentration lower than that of the source layer 32. The n-type impurity concentration of the drift layer 38 is 9×10¹⁷ cm⁻³ or less. The drift layer 38 is disposed below each body layer 36. The drift layer 38 is distributed up to the upper surface 12a at a position between the two body layers 36 and in contact with the side surfaces of both the body layers 36. The drift layer 38 is in contact with the gate insulating film 20 at a position adjacent to the body layer 36. The drift layer 38 is separated from the source layer 32 by the body layer 36.

The buffer layer 40 is an n-type layer having an n-type impurity concentration higher than the drift layer 38. The n-type impurity concentration of the buffer layer 40 is higher than 9×10¹⁷ cm⁻³. The buffer layer 40 is in contact with the drift layer 38 from below.

The drain layer 42 is an n-type layer having an n-type impurity concentration higher than that of the buffer layer 40. The drain layer 42 is in contact with the buffer layer 40 from below. The drain layer 42 is in ohmic contact with the drain electrode 28 on the lower surface 12b of the semiconductor substrate 12.

Each of the lower p-layers 52 is disposed below a corresponding body layer 36. Each of the lower p-layers 52 is in contact with the corresponding body layer 36 from below. The bottom surface and side surfaces of each lower p-layer 52 are in contact with the drift layer 38.

The p-type impurity concentration distribution in each lower p-layer 52 is equal to the p-type impurity concentration in the lower p-layer 52 of the first embodiment, as shown in FIG. 2. That is, each of the lower p-layers 52 has a high-concentration layer 52a and a low-concentration layer 52b. The low-concentration layer 52b includes an upper low-concentration layer 52bU disposed above the high-concentration layer 52a, and a lower low-concentration layer 52bL disposed below the high-concentration layer 52a. The lower low-concentration layer 52bL has a region 52c having a p-type impurity concentration higher than the average value A of the p-type impurity concentration of the low-concentration layer 52b. The thickness x0 of the region 52c is greater than the smaller of the thicknesses x1 and x2 obtained by the above mathematical equations (1) and (2). Therefore, when the switching element 100 of the second embodiment is turned off, the depletion layer extending from the lower surface (i.e., the pn junction) of each lower p-layer 52 to the inside of each lower p-layer 52 does not reach the high-concentration layer 52a. As such, the leakage current is also suppressed in the switching element of the second embodiment. Also in the switching element of the second embodiment, the lower p-layer 52 suppresses the injection of holes into the gate insulating film 20.

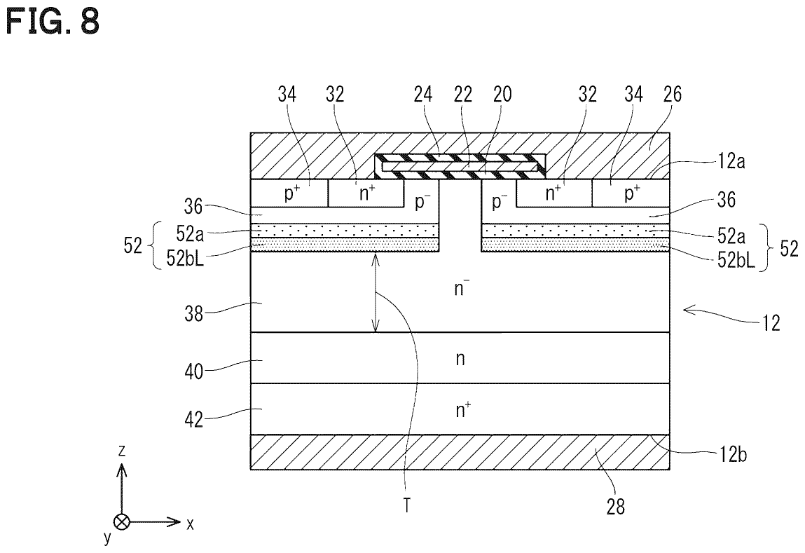

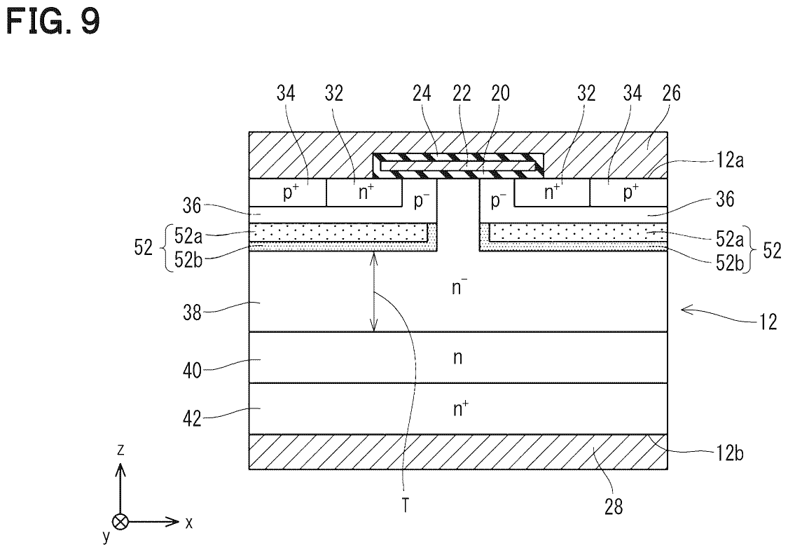

In the second embodiment, the upper low-concentration layer 52bU is provided above the high-concentration layer 52a. Alternatively, as a modified example, the upper low-concentration layer 52bU may not be provided, and the high-concentration layer 52a may be in direct contact with the body layer 36, as shown in FIG. 8. Also in such a configuration, since the lower low-concentration layer 52bL is present below the high-concentration layer 52a, the depletion layer does not reach the high-concentration layer 52a. Therefore, the leakage current can be suppressed. In the case where the upper low-concentration layer 52bU is not provided, the low-concentration layer 52b may be provided on the sides and below the high-concentration layer 52a, as shown in FIG. 9.

In the second embodiment, the buffer layer 40 is provided between the drift layer 38 and the drain layer 42. Alternatively, the buffer layer 40 may not be provided. In each of the embodiments described above, the concentrations of the drift layer 38 and the buffer layer 40 may be adjusted during epitaxial growth of the drift layer 38 and the buffer layer 40. Alternatively, the concentrations of the drift layer 38 and the buffer layer 40 may be adjusted by ion implantation after the epitaxial growth.

Although the embodiments have been described in detail above, these are merely examples and do not limit the scope of claims. The techniques described in the claims include various modifications and modifications of the specific examples illustrated above. The technical elements described in this specification or the drawings exhibit technical usefulness alone or in various combinations, and are not limited to the combinations described in the claims at the time of filing. In addition, the techniques illustrated in the present specification or drawings achieve objectives at the same time, and achieving one of the objectives itself has technical usefulness.

What is claimed is:

1. A switching element comprising:
a semiconductor substrate made of silicon carbide; and
a gate electrode facing the semiconductor substrate via a gate insulating film, wherein
the semiconductor substrate includes:
a source layer of an n-type in contact with the gate insulating film;
a body layer of a p-type in contact with the gate insulating film and the source layer;
a drift layer of an n-type in contact with the gate insulating film and the body layer and separated from the source layer by the body layer; and
at least one of a first lower p-layer in contact with the gate insulating film from below and in contact with the drift layer from above or a second lower p-layer in contact with the body layer from below and in contact with the drift layer from above,
the at least one of the first lower p-layer or the second lower p-layer includes:
a high-concentration layer having a p-type impurity concentration equal to or greater than half of a maximum value of a p-type impurity concentration in the at least one of the first lower p-layer or the second lower p-layer; and
a low-concentration layer having a p-type impurity concentration smaller than the half of the maximum value,
the low-concentration layer has a lower low-concentration layer disposed between the high-concentration layer and the drift layer in a thickness direction of the semiconductor substrate, and
a part of the lower low-concentration layer having a p-type impurity concentration higher than an average value A of a p-type impurity concentration of the lower low-concentration layer has a predetermined thickness that is greater than a smaller of thicknesses x1 and x2 obtained by following mathematical equations (1) and (2):
$$\begin{matrix}x 1 = \frac{C \cdot T}{A} & ( 1 ) \\ \{ \begin{matrix}x 2 = \sqrt{\frac{2 \cdot ε}{q \cdot A} \cdot \frac{C}{A + C} \cdot ( {V}_{bi} + {V}_{BV} )} \\ {V}_{bi} = \frac{298 k}{q} ln ( \frac{A \cdot C}{{n}_{i}^{2}} )\end{matrix} & ( 2 )\end{matrix}$$
in which a symbol C represents an average value of an n-type impurity concentration of the drift layer below the at least one of the first lower p-layer or the second lower p-layer, a symbol T represents a thickness of the drift layer below the at least one of the first lower p-layer or the second lower p-layer, a symbol ε represents a dielectric constant of the silicon carbide, a symbol q is an elementary charge, a symbol V_{bi} represents a built-in potential at an interface between the low-concentration layer and the drift layer, a symbol V_{BV} represents a maximum rated voltage between a drain and a source of the switching element, a symbol k represents a Boltzmann constant, and a symbol nᵢ is an intrinsic carrier density of the silicon carbide.

2. The switching element according to claim 1, wherein
the semiconductor substrate is formed with a trench in an upper surface thereof,
the gate insulating film and the gate electrode are disposed in the trench, and
the semiconductor substrate includes the first lower p-layer that is in contact with the gate insulating film at a bottom surface of the trench.

3. The switching element according to claim 1, wherein
the semiconductor substrate includes the second lower p-layer that is in contact with the body layer from below.
